(19) United States
(12) Patent Application Publication
(10) Pub. No.: US 2026/0129861 A1
(43) Pub. Date: May 7, 2026

(54) FABRICATION METHOD FOR METAL-GATE 1.5T-STRUCTURE SONOS MEMORY

(71) Applicant: Shanghai Huali Integrated Circuit Corporation, Shanghai (CN)

(72) Inventor: Xiaoliang TANG, Shanghai (CN)

(73) Assignee: Shanghai Huali Integrated Circuit Corporation, Shanghai (CN)

(21) Appl. No.: 19/244,623

(22) Filed: Jun. 20, 2025

(30) Foreign Application Priority Data
Nov. 7, 2024 (CN) 202411589290.8

(51) Int. Cl. H10B 43/40

(52) U.S. Cl. CPC H10B 43/40

(57) ABSTRACT

The present application discloses a fabrication method for a metal-gate 1.5T-structure SONOS memory, and a selection transistor and a storage transistor use the same storage unit gate polysilicon layer; and when removal of dummy polysilicon, by a mask, a storage unit gate stack of a storage transistor gate area is first removed and a storage unit gate stack of a selection transistor gate area is retained, a semiconductor substrate under the storage transistor gate area is exposed, a storage transistor gate structure slot is formed, then an ONO layer is deposited to enable the ONO layer to cover a bottom and a sidewall of the storage transistor gate structure slot, and then a first gate metal layer is deposited on the ONO layer to form a storage transistor metal gate. The present application can form a smaller-size metal-gate 1.5T-structure SONOS memory and require less masks.

### CROSS-REFERENCE TO RELATED APPLICATIONS

This application claims priority to Chinese patent application No. 202411589290.8, filed on Nov. 7, 2024, the disclosure of which is incorporated herein by reference in its entirety.

### TECHNICAL FIELD

The present application relates to semiconductor manufacturing technology, and particularly to a fabrication method for a metal-gate 1.5T-structure SONOS memory.

### BACKGROUND

In a semiconductor integrated circuit, a flash memory is widely used, due to its non-volatile feature, in consumer electronics and portable systems such as a cell phone, a digital camera, etc. Non-volatile storage technology mainly includes floating gate technology, split gate technology and Silicon-Oxide-Nitride-Oxide-Silicon-Silicon (SONOS) technology, and a SONOS-type flash memory is widely used due to advantages such as a simple process, a low operating voltage, a high data reliability, ease of integration into standard CMOS processes, etc.

A traditional SONOS storage unit has a 2T (transistor) structure, including two transistors that can operate independently, one is a selection transistor (SG, select gate), and the other one is a memory transistor (MG, memory gate), using an ONO (SiO2-Si3N4-SiO2) layer as a gate dielectric layer, which can store charge in Si3N4 therein. And, a 1.5T-structure SONOS storage unit having two transistors disposed close to each other can have a significantly reduced storage unit area than the 2T structure, but need two layers of gate polysilicon, and thus need two performed polysilicon deposition (poly dep) processes, adding additional masks and processes with a very difficult process. With the process of a technology node, a logic process has been transitioned to a metal gate process staring from 28 nm, and a 1.5T-production process is more complex.

Currently, a mainstream fabrication method for a 1.5T-structure SONOS memory includes: after depositing a first layer of gate polysilicon, first etching to form a gate of one device of a SONOS storage unit, which gate may be a selection transistor or a storage transistor, then further producing gate dielectrics of another device and a peripheral logic device (such as a core device, and an input-output device) of the memory, and then depositing a second layer of polysilicon which is utilized to produce a gate of the peripheral logic device of the memory, and is utilized to form a gate of another device to complete fabrication of the 1.5T-structure SONOS memory.

As described above, after completing the first device of the 1.5T-structure SONOS memory, additional masks and processes need to be added to correctly form the gate dielectrics of the second device and peripheral logic device, and to correctly form the shape of the second gate when gate etching is performed on the second layer of polysilicon, increasing process complexity and cost, and a formation process for the 1.5T SONOS storage unit and a fabrication process of a logic device can interact with each other, thereby affecting device performance.

### BRIEF SUMMARY

The present application provides a fabrication method for a metal-gate 1.5T-structure SONOS memory, which includes the following steps:
S1. providing a semiconductor substrate 100, the semiconductor substrate 100 being formed with a logic device active area 102 and a SONOS storage unit active area 103 separated by a shallow trench isolation 110;
S2. forming a gate oxide layer 130 on the semiconductor substrate;
S3. depositing a gate polysilicon layer 140 on the gate oxide layer 130;
S4. photoetching to define a storage unit gate area in the SONOS storage unit active area 103 and a logic device gate area in the logic device active area 102; and etching which stops on the semiconductor substrate 100 and the shallow trench isolation 110, to remove a gate polysilicon layer 140 and a gate oxide layer 130 outside the storage unit gate area and the logic device gate area, to form a storage unit gate stack on a semiconductor substrate 100 of the storage unit gate area, and to form a logic device gate stack on a semiconductor substrate 100 of the logic device gate area; and the storage unit gate stack being a storage unit gate oxide layer 131 and a storage unit gate polysilicon layer 141 stacked from top to bottom, and the logic device gate stack being a logic device gate oxide layer 132 and a logic device gate polysilicon layer 142 stacked from top to bottom;
S5. forming an interlayer dielectric layer 120 covering the semiconductor substrate 100, and then performing chemical mechanical polishing to expose upper surfaces of the storage unit gate polysilicon layer 141 and the logic device gate polysilicon layer 142;
S6. photoetching to define a selection transistor gate area and a storage transistor gate area that are adjacent from left to right in the storage unit gate area; and etching which stops on the semiconductor substrate 100 to remove the storage unit gate stack of the storage transistor gate area and retain a storage unit gate stack of the selection transistor gate area, to expose a semiconductor substrate 100 under the storage transistor gate area, and to form a storage transistor gate structure slot 181;
S7. depositing an ONO layer 150 on a silicon wafer to enable the ONO layer 150 to cover a bottom and a sidewall of the storage transistor gate structure slot 181 to form a storage transistor gate slot 182, the ONO layer 150 covering exposed upper surfaces of the storage unit gate polysilicon layer 141 and the logic device gate polysilicon 142;
S8. depositing a first gate metal layer 161 on the ONO layer 150;
S9. performing chemical mechanical polishing to remove a first gate metal layer 161 outside the storage transistor gate slot 182 to expose an upper surface of storage unit gate polysilicon 141 of a remaining selection transistor gate stack and an upper surface of the logic device gate polysilicon 142;
S10. removing the storage unit gate polysilicon 141 of the storage unit gate stack of the selection transistor gate area to stop at the storage unit gate oxide layer 131 to form a selection transistor gate slot 183; and removing the logic device gate polysilicon 142 to stop at the logic device gate oxide layer 132 to form a logic device gate slot 184;
S11. depositing a second gate metal layer 162;
S12. performing chemical mechanical polishing to remove a second gate metal layer 162 outside the selection transistor gate slot 183 and the logic device gate slot 184 to form a selection transistor metal gate, a logic device metal gate, and a storage transistor metal gate; and
S13. performing a subsequent process for a SONOS storage unit and a logic device to complete fabrication of the 1.5T-structure SONOS memory.

In some embodiments, in step S1, a well implantation process is performed on the active area to form a P-well or an N-well.

In some embodiments, the logic device active area 102 includes a core device active area, and an input-output device active area.

In some embodiments, in step S2, the gate oxide layer 130 is formed using an oxidization process.

In some embodiments, in step S3, the gate polysilicon layer 140 is formed using a low-pressure chemical vapor deposition process.

In some embodiments, in step S7, the ONO layer 150 is formed by deposition using a low-pressure chemical vapor deposition process (LPCVD) or an atomic layer deposition (ALD).

In some embodiments, the first gate metal layer 161 is AL; and the second gate metal layer 162 is AL.

In some embodiments, in step S4, the storage unit gate stack is formed on the SONOS storage unit active area 103, the logic device gate stack is formed on the logic device active area 102, and then a spacer 190 is formed on transverse peripheries of the storage unit gate stack and the logic device gate stack.

In some embodiments, in step S13, an LDD ion implantation process step is performed.

In some embodiments, in step S13, an annealing process step is performed.

In some embodiments, in step S4, a gate oxide layer 130 outside the storage unit gate area and the logic device gate area is removed by washing by hydrofluoric acid (HF).

In some embodiments, after step S6, an exposed semiconductor substrate 100 under the storage transistor gate area is subjected to threshold voltage Vt-adjusted ion implantation, and then proceed to step 7.

In the fabrication method for a metal-gate 1.5T-structure SONOS memory of the present application, after deposing the gate polysilicon layer 140 on the gate oxide layer 130, by photoetching, the storage unit gate area is defined in the SONOS storage unit active area 103 and the logic device gate area is defined in the logic device active area 102; then etching removes the gate polysilicon layer 140 and gate oxide layer 130 outside the storage unit gate area and the logic device gate area, the storage unit gate stack is formed on the semiconductor substrate 100 of the storage unit gate area, the logic device gate stack is formed on the semiconductor substrate 100 of the logic device gate area, and a selection transistor and a storage transistor use the same storage unit gate polysilicon layer 141; and when removal of dummy polysilicon, by a mask, the storage unit gate stack of the storage transistor gate area is first removed and the storage unit gate stack of the selection transistor gate area is retained, the semiconductor substrate 100 under the storage transistor gate area is exposed, the storage transistor gate structure slot 181 is formed, then the ONO layer 150 is deposited to enable the ONO layer 150 to cover the bottom and sidewall of the storage transistor gate structure slot 181 to form a storage transistor gate slot 182, then the first gate metal layer 161 is deposited on the ONO layer 500 and the chemical mechanical polishing (CMP) is performed to form the storage transistor metal gate. The fabrication method for a metal-gate 1.5T-structure SONOS memory can form a smaller-size metal-gate 1.5T-structure SONOS memory by process improvements and can reduce a mask relative to a fabrication process for a conventional metal-gate 2T-structure SONOS memory.

### BRIEF DESCRIPTION OF THE DRAWINGS

To more clearly illustrate the technical solution of the present application, the figures used in the present application are briefly introduced below. Obviously, the figures in the description below are only some embodiments of the present application, and for a person of ordinary skill in the art, according to these figures, other figures can be obtained without inventive effort.

FIG. 1 is a sectional view of a semiconductor substrate in an embodiment of the fabrication method for a metal-gate 1.5T-structure SONOS memory of the present application;

FIG. 2 is a sectional view of forming a gate oxide layer in an embodiment of the fabrication method for a metal-gate 1.5T-structure SONOS memory of the present application;

FIG. 3 is a sectional view of depositing a gate polysilicon layer in an embodiment of the fabrication method for a metal-gate 1.5T-structure SONOS memory of the present application;

FIG. 4 is a sectional view of forming a memory unit gate stack in an embodiment of the fabrication method for a metal-gate 1.5T-structure SONOS memory of the present application;

FIG. 5 is a sectional view of polishing an interlayer dielectric layer in an embodiment of the fabrication method for a metal-gate 1.5T-structure SONOS memory of the present application;

FIG. 6 is a sectional view of forming a storage transistor gate structure slot in an embodiment of the fabrication method for a metal-gate 1.5T-structure SONOS memory of the present application;

FIG. 7 is a sectional view of depositing an ONO layer in an embodiment of the fabrication method for a metal-gate 1.5T-structure SONOS memory of the present application;

FIG. 8 is a sectional view of depositing a first gate metal layer in an embodiment of the fabrication method for a metal-gate 1.5T-structure SONOS memory of the present application;

FIG. 9 is a sectional view of polishing a first gate metal layer in an embodiment of the fabrication method for a metal-gate 1.5T-structure SONOS memory of the present application;

FIG. 10 is a sectional view of forming a selection transistor gate slot in an embodiment of the fabrication method for a metal-gate 1.5T-structure SONOS memory of the present application;

FIG. 11 is a sectional view of depositing a second gate metal layer in an embodiment of the fabrication method for a metal-gate 1.5T-structure SONOS memory of the present application; and

FIG. 12 is a sectional view of forming a selection transistor metal gate, a logic device metal gate and a storage transistor metal gate in an embodiment of the fabrication method for a metal-gate 1.5T-structure SONOS memory of the present application.

### DESCRIPTION OF REFERENCE NUMBERS IN THE FIGURES

100. Semiconductor substrate; 110. Shallow trench isolation; 102. Logic device active area; 103. SONOS storage unit active area; 130. Gate oxide layer; 140. Gate polysilicon layer; 131. Storage unit gate oxide layer; 141. Storage unit gate polysilicon layer; 132. Logic device gate oxide layer 132; 142. Logic device gate polysilicon layer; 120. Interlayer dielectric layer; 181 Storage transistor gate structure slot; 150. ONO layer; 182. Storage transistor gate slot; 161. First gate metal layer; 183. Selection transistor gate slot; 184. Logic device gate slot; 162. Second gate metal layer; 190. Spacer.

### DETAILED DESCRIPTION OF THE DISCLOSURE

The technical solution in the embodiment of the present application is described clearly below in conjunction with the figures. Obviously, the described embodiments are a part of the embodiments of the present application, not all the embodiments. Based on the embodiments in the present application, all other embodiments obtained by those of ordinary skill in the art without the exercise of inventive effort fall within the scope of protection of the present application.

### Embodiment I

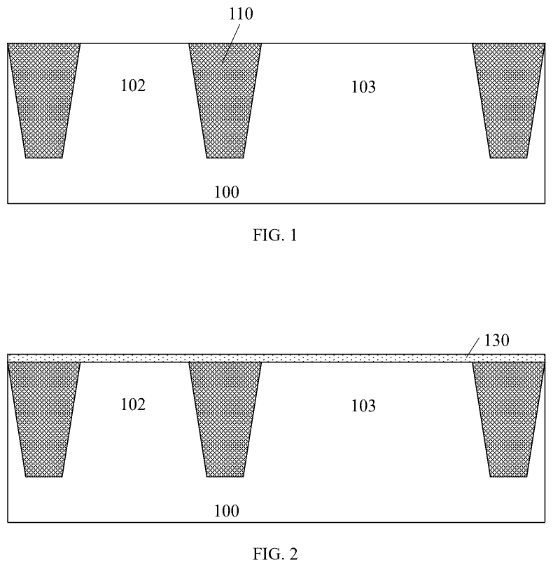

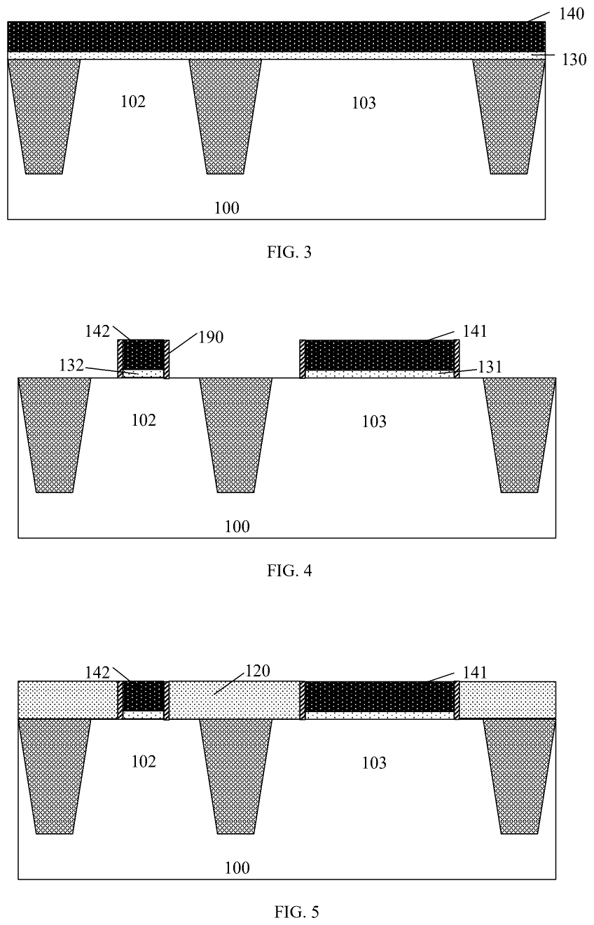

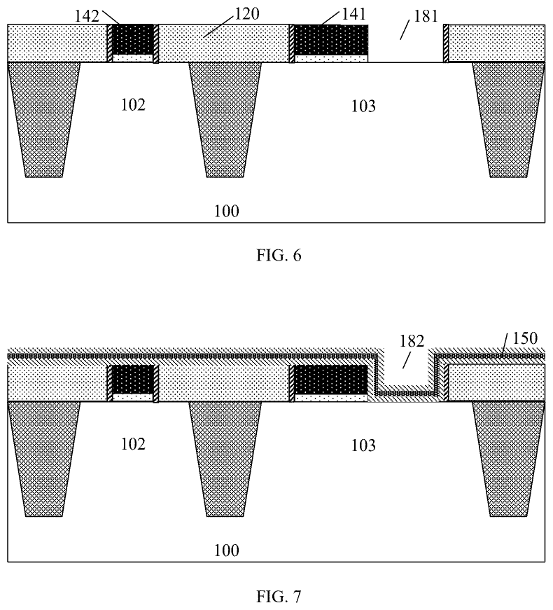

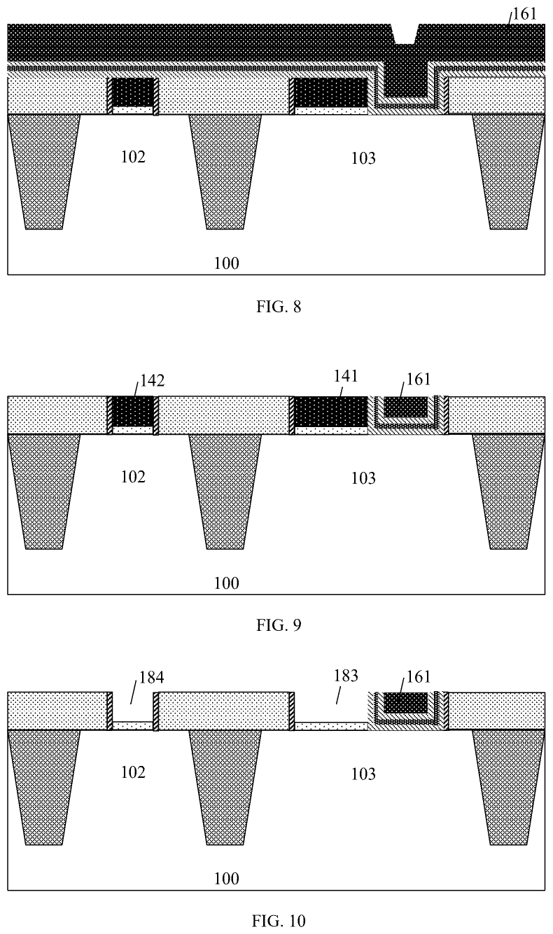

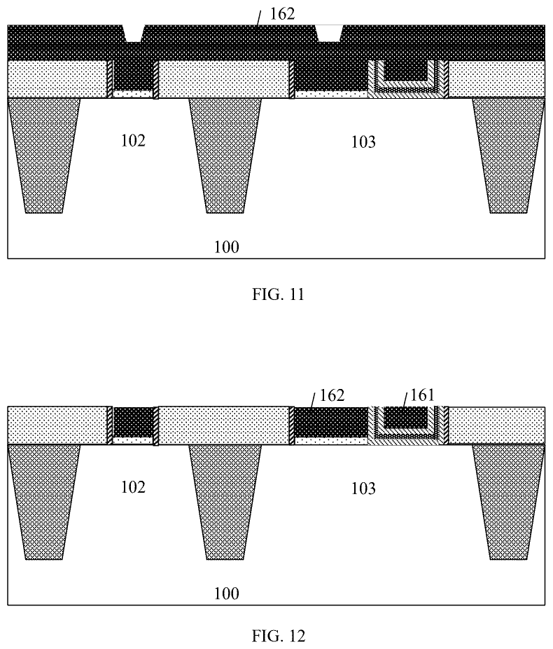

A fabrication method for a metal-gate 1.5T-structure SONOS memory includes the following steps:
S1. providing a semiconductor substrate 100, the semiconductor substrate 100 being formed with a logic device active area 102 and a SONOS storage unit active area 103 separated by a shallow trench isolation 110, referring to FIG. 1;
S2. forming a gate oxide layer 130 on the semiconductor substrate, referring to FIG. 2;
S3. depositing a gate polysilicon layer 140 on the gate oxide layer 130, referring to FIG. 3;
S4. photoetching to define a storage unit gate area in the SONOS storage unit active area 103 and a logic device gate area in the logic device active area 102; and etching which stops on the semiconductor substrate 100 and the shallow trench isolation 110, to remove a gate polysilicon layer 140 and a gate oxide layer 130 outside the storage unit gate area and the logic device gate area, to form a storage unit gate stack on a semiconductor substrate 100 of the storage unit gate area, and to form a logic device gate stack on a semiconductor substrate 100 of the logic device gate area; and the storage unit gate stack being a storage unit gate oxide layer 131 and a storage unit gate polysilicon layer 141 stacked from top to bottom, and the logic device gate stack being a logic device gate oxide layer 132 and a logic device gate polysilicon layer 142 stacked from top to bottom, referring to FIG. 4;
S5. forming an interlayer dielectric layer 120 covering the semiconductor substrate 100, and then performing chemical mechanical polishing (CMP) to expose upper surfaces of the storage unit gate polysilicon layer 141 and the logic device gate polysilicon layer 142, referring to FIG. 5;
S6. photoetching to define a selection transistor gate area and a storage transistor gate area that are adjacent from left to right in the storage unit gate area; and etching which stops on the semiconductor substrate 100 to remove the storage unit gate stack of the storage transistor gate area and retain a storage unit gate stack of the selection transistor gate area, to expose a semiconductor substrate 100 under the storage transistor gate area, and to form a storage transistor gate structure slot 181, referring to FIG. 6;
S7. depositing an ONO (SiO2-Si3N4-SiO2) layer 150 on a silicon wafer to enable the ONO layer 150 to cover a bottom and a sidewall of the storage transistor gate structure slot 181 to form a storage transistor gate slot 182, the ONO layer 150 covering exposed upper surfaces of the storage unit gate polysilicon layer 141 and the logic device gate polysilicon 142, referring to FIG. 7;
S8. depositing a first gate metal layer 161 on the ONO layer 150, referring to FIG. 8;
S9. performing chemical mechanical polishing to remove a first gate metal layer 161 outside the storage transistor gate slot 182 to expose an upper surface of storage unit gate polysilicon 141 of a remaining selection transistor gate stack and an upper surface of the logic device gate polysilicon 142, referring to FIG. 9;
S10. removing the storage unit gate polysilicon 141 of the storage unit gate stack of the selection transistor gate area to stop at the storage unit gate oxide layer 131 to form a selection transistor gate slot 183; and removing the logic device gate polysilicon 142 to stop at the logic device gate oxide layer 132 to form a logic device gate slot 184, referring to FIG. 10;
S11. depositing a second gate metal layer 162, referring to FIG. 11;
S12. performing chemical mechanical polishing (CMP) to remove a second gate metal layer 162 outside the selection transistor gate slot 183 and the logic device gate slot 184 to form a selection transistor metal gate, a logic device metal gate, and a storage transistor metal gate, referring to FIG. 12; and
S13. performing a subsequent process for a SONOS storage unit and a logic device to complete fabrication of the 1.5T-structure SONOS memory.

In the fabrication method for a metal-gate 1.5T-structure SONOS memory of embodiment I, after deposing the gate polysilicon layer 140 on the gate oxide layer 130, by photoetching, the storage unit gate area is defined in the SONOS storage unit active area 103 and the logic device gate area is defined in the logic device active area 102; then etching removes the gate polysilicon layer 140 and gate oxide layer 130 outside the storage unit gate area and the logic device gate area, the storage unit gate stack is formed on the semiconductor substrate 100 of the storage unit gate area, the logic device gate stack is formed on the semiconductor substrate 100 of the logic device gate area, and a selection transistor and a storage transistor use the same storage unit gate polysilicon layer 141; and when removal of dummy polysilicon, by a mask, the storage unit gate stack of the storage transistor gate area is first removed and the storage unit gate stack of the selection transistor gate area is retained, the semiconductor substrate 100 under the storage transistor gate area is exposed, the storage transistor gate structure slot 181 is formed, then the ONO layer 150 is deposited to enable the ONO layer 150 to cover the bottom and sidewall of the storage transistor gate structure slot 181 to form a storage transistor gate slot 182, then the first gate metal layer 161 is deposited on the ONO layer 500 and the chemical mechanical polishing (CMP) is performed to form the storage transistor metal gate. The fabrication method for a metal-gate 1.5T-structure SONOS memory in embodiment I can form a smaller-size metal-gate 1.5T-structure SONOS memory by process improvements and can reduce a mask relative to a fabrication process for a conventional metal-gate 2T-structure SONOS memory.

### Embodiment II

Based on the fabrication method for a metal-gate 1.5T-structure SONOS memory of embodiment I, in step S1, a well implantation process is performed on the active area to form a P-well or an N-well; typically, the logic device active area 102 includes an active area of a core device, and an active area of an input-output (IO) device, the logic device active area 102 is used to form a logic device, the logic device active area 102 can be divided into a core device active area and an input-output (IO) device active area, a core device is formed in the core device active area, and an input-output device is formed in the input-output (IO) device active area; and the SONOS storage unit active area 103 is used to form a selection transistor (SG, select gate) and a memory transistor (MG, memory gate) of a SONOS storage unit.

Preferably, in step S2, the gate oxide layer 130 is formed using an oxidization process.

Preferably, in step S3, the gate polysilicon layer 140 is formed using a low-pressure chemical vapor deposition process (LPCVD).

Preferably, in step S7, the ONO layer 150 is formed by deposition using a low-pressure chemical vapor deposition process (LPCVD) or an atomic layer deposition (ALD).

Preferably, the first gate metal layer 161 is AL.

Preferably, the second gate metal layer 162 is AL.

### Embodiment III

Based on the fabrication method for a metal-gate 1.5T-structure SONOS memory of embodiment I, in step S4, the storage unit gate stack is formed on the SONOS storage unit active area 103, the logic device gate stack is formed on the logic device active area 102, and then a spacer 190 is formed on transverse peripheries of the storage unit gate stack and the logic device gate stack.

Preferably, in step S4, a gate oxide layer 130 outside the storage unit gate area and the logic device gate area is removed by washing by hydrofluoric acid (HF).

Preferably, after step S6, an exposed semiconductor substrate 100 under the storage transistor gate area is subjected to threshold voltage Vt-adjusted ion implantation, and then proceed to step 7.

### Embodiment IV

Based on the fabrication method for a metal-gate 1.5T-structure SONOS memory of embodiment I, in step S13, process steps such as an LDD (lightly doped drain) ion implantation, annealing, etc. are performed to complete fabrication of the 1.5T-structure SONOS memory.

Only preferred embodiments of the present application are described above and are not intended to limit the present application. Any modifications, equivalent replacements, improvements, etc. made within the spirit and principle of the present application shall be included within the scope of protection of the present application.

What is claimed is:

1. A fabrication method for a metal-gate 1.5T-structure SONOS memory, comprising the following steps:
S1. providing a semiconductor substrate, the semiconductor substrate being formed with a logic device active area and a SONOS storage unit active area separated by a shallow trench isolation;
S2. forming a gate oxide layer on the semiconductor substrate;
S3. depositing a gate polysilicon layer on the gate oxide layer;
S4. photoetching to define a storage unit gate area in the SONOS storage unit active area and a logic device gate area in the logic device active area; and
etching which stops on the semiconductor substrate and the shallow trench isolation, to remove a gate polysilicon layer and a gate oxide layer outside the storage unit gate area and the logic device gate area, to form a storage unit gate stack on a semiconductor substrate of the storage unit gate area, and to form a logic device gate stack on a semiconductor substrate of the logic device gate area; and the storage unit gate stack being a storage unit gate oxide layer and a storage unit gate polysilicon layer stacked from top to bottom, and the logic device gate stack being a logic device gate oxide layer and a logic device gate polysilicon layer stacked from top to bottom;
S5. forming an interlayer dielectric layer covering the semiconductor substrate, and then performing chemical mechanical polishing to expose upper surfaces of the storage unit gate polysilicon layer and the logic device gate polysilicon layer;
S6. photoetching to define a selection transistor gate area and a storage transistor gate area that are adjacent from left to right in the storage unit gate area; and
etching which stops on the semiconductor substrate to remove the storage unit gate stack of the storage transistor gate area and retain a storage unit gate stack of the selection transistor gate area, to expose a semiconductor substrate under the storage transistor gate area, and to form a storage transistor gate structure slot;
S7. depositing an ONO layer on a silicon wafer to enable the ONO layer to cover a bottom and a sidewall of the storage transistor gate structure slot to form a storage transistor gate slot, the ONO layer covering exposed upper surfaces of the storage unit gate polysilicon layer and the logic device gate polysilicon;
S8. depositing a first gate metal layer on the ONO layer;
S9. performing chemical mechanical polishing to remove a first gate metal layer outside the storage transistor gate slot to expose an upper surface of storage unit gate polysilicon of a remaining selection transistor gate stack and an upper surface of the logic device gate polysilicon;
S10. removing the storage unit gate polysilicon of the storage unit gate stack of the selection transistor gate area to stop at the storage unit gate oxide layer to form a selection transistor gate slot; and removing the logic device gate polysilicon to stop at the logic device gate oxide layer to form a logic device gate slot;
S11. depositing a second gate metal layer;
S12. performing chemical mechanical polishing to remove a second gate metal layer outside the selection transistor gate slot and the logic device gate slot to form a selection transistor metal gate, a logic device metal gate, and a storage transistor metal gate; and
S13. performing a subsequent process for a SONOS storage unit and a logic device to complete fabrication of the 1.5T-structure SONOS memory.

2. The fabrication method for a metal-gate 1.5T-structure SONOS memory according to claim 1, wherein
in step S1, a well implantation process is performed on the active area to form a P-well or an N-well.

3. The fabrication method for a metal-gate 1.5T-structure SONOS memory according to claim 1, wherein
the logic device active area comprises a core device active area, and an input-output device active area.

4. The fabrication method for a metal-gate 1.5T-structure SONOS memory according to claim 1, wherein
in step S2, the gate oxide layer is formed using an oxidization process.

5. The fabrication method for a metal-gate 1.5T-structure SONOS memory according to claim 1, wherein
in step S3, the gate polysilicon layer is formed using a low-pressure chemical vapor deposition process.

6. The fabrication method for a metal-gate 1.5T-structure SONOS memory according to claim 1, wherein
in step S7, the ONO layer is formed by deposition using a low-pressure chemical vapor deposition process or an atomic layer deposition.

7. The fabrication method for a metal-gate 1.5T-structure SONOS memory according to claim 1, wherein
the first gate metal layer is AL; and
the second gate metal layer is AL.

8. The fabrication method for a metal-gate 1.5T-structure SONOS memory according to claim 1, wherein
in step S4, the storage unit gate stack is formed on the SONOS storage unit active area, the logic device gate stack is formed on the logic device active area, and then a spacer 190 is formed on transverse peripheries of the storage unit gate stack and the logic device gate stack.

9. The fabrication method for a metal-gate 1.5T-structure SONOS memory according to claim 1, wherein
in step S13, an LDD ion implantation process step is performed.

10. The fabrication method for a metal-gate 1.5T-structure SONOS memory according to claim 1, wherein
in step S13, an annealing process step is performed.

11. The fabrication method for a metal-gate 1.5T-structure SONOS memory according to claim 1, wherein
in step S4, a gate oxide layer outside the storage unit gate area and the logic device gate area is removed by washing by hydrofluoric acid.

12. The fabrication method for a metal-gate 1.5T-structure SONOS memory according to claim 1, wherein
after step S6, an exposed semiconductor substrate under the storage transistor gate area is subjected to threshold voltage-adjusted ion implantation, and then proceed to step 7.
